(19) United States
(12) Patent Application Publication
(10) Pub. No.: US 2024/0322064 A1
(43) Pub. Date: Sep. 26, 2024

(54) Photodiodes

(71) Applicant: X-FAB Global Services GmbH, Erfurt (DE)

(72) Inventors: Daniel Gäbler, Apolda (DE); Pablo Siles, Erfurt (DE); Qiang Ai, Kuching (MY); Tamer Abdulrahman, Évry (FR)

(21) Appl. No.: 18/609,426

(22) Filed: Mar. 19, 2024

(30) Foreign Application Priority Data
Mar. 20, 2023 (GB) 2304001.7

(51) Int. Cl. H01L 31/18; H01L 31/0216; H01L 31/0352; H01L 31/103

(52) U.S. Cl. CPC H01L 31/1804; H01L 31/02161; H01L 31/03529; H01L 31/103; H01L 31/1868

(57) ABSTRACT

A method of forming a photodiode including providing a semiconductor wafer and performing a first doping step to form a first well in the wafer having a first type of doping. The method further includes performing a second doping step to form a second well having a second type of doping, so as to form a pn-junction of the photodiode between the first well and the second well. The method includes performing a shallow trench isolation etch to form a plurality of trenches in a surface of the wafer in the second well, and performing a third doping step by injecting dopants at a first angle relative to the surface of the wafer in order to increase a doping concentration of the second type of doping along the sides of the trenches in the second well. The method includes performing a fourth doping step by injecting dopants at a second angle relative to the surface of the wafer in order to increase a doping concentration of the second type of doping at the bottom of the trenches in the second well. The method includes performing a fifth doping step to increase a doping concentration of the second type of doping at the surface of the semiconductor wafer between the trenches in the second well, and forming a first contact for contacting the first well and forming a second contact for contacting the second well in order to apply a voltage across the pn-junction when in use.

This application claims priority to United Kingdom Application No. 2304001.7 filed on Mar. 20, 2023 and entitled “Photodiodes,” the entire contents of which are hereby incorporated by reference.

### TECHNICAL FIELD

The invention relates photodiodes, and in particular to photodiodes having a high sensitivity in the ultraviolet range.

### BACKGROUND

Photodiodes are used in a wide range of applications for detecting and measuring electromagnetic radiation. The high refractive index of the semiconductor material can cause a significant amount of light to be reflected before it enters the light sensitive region of the photodiode, with the result that this light is not available for sensing and the quantum efficiency of the device is degraded.

The reflection losses can be reduced by creating a graded index using an effective medium by forming a layer comprising different proportions of materials having different refractive indices. Using shallow trench isolation (STI), relatively small features can be etched in the surface of the semiconductor material and filled with silicon oxide to create an effective medium in order to reduce reflection losses.

However, there may be a continued need for improvements to the sensitivity and durability of photodiodes.

### SUMMARY

A potential problem with the use of an effective medium in the light sensitive area is the increased interface length, which can trap light generated charge carriers and thereby reduce sensitivity. In particular for UV light, the penetration depth is low, causing a relatively high concentration of charge carriers generated close to the interface, where there is a greater chance of trapping.

To at least partly solve this problem the present disclosure provides an improved photodiode and method of forming such as set out in the accompanying claims.

Specific embodiments are described below with reference to the drawings.

### BRIEF DESCRIPTION OF DRAWINGS

FIG. 1 shows a schematic cross section of a part of a semiconductor structure comprising a photodiode;

FIG. 2 shows a schematic cross section of a part of a photodiode;

FIG. 3 shows a graph of a doping profile of a photodiode;

FIG. 4A is a first step showing a sequence of schematic diagrams illustrating a method of forming a photodiode;

FIG. 4B is another step showing a sequence of schematic diagrams illustrating a method of forming a photodiode;

FIG. 4C is another step showing a sequence of schematic diagrams illustrating a method of forming a photodiode;

FIG. 4D is another step showing a sequence of schematic diagrams illustrating a method of forming a photodiode;

FIG. 4E is another step showing a sequence of schematic diagrams illustrating a method of forming a photodiode;

FIG. 4F is another step showing a sequence of schematic diagrams illustrating a method of forming a photodiode;

FIG. 5 shows a schematic top view of a semiconductor structure comprising a photodiode; and

FIG. 6 shows a flow diagram illustrating the steps of a method of forming a photodiode.

### DETAILED DESCRIPTION

The present disclosure provides a method of forming a photodiode using a specific sequence of doping steps together with the steps of forming the effective medium, which can reduce the chance of trapped charge carriers and thereby increase the sensitivity to UV light. In particular, the method comprises doping the sides and bottom of the trenches formed in the light sensitive area with two injection steps at different angles. A high doping concentration along the interface that steadily decreases towards the pn-junction pushes generated charge carriers away from the interface and towards the pn-junction (for detection).

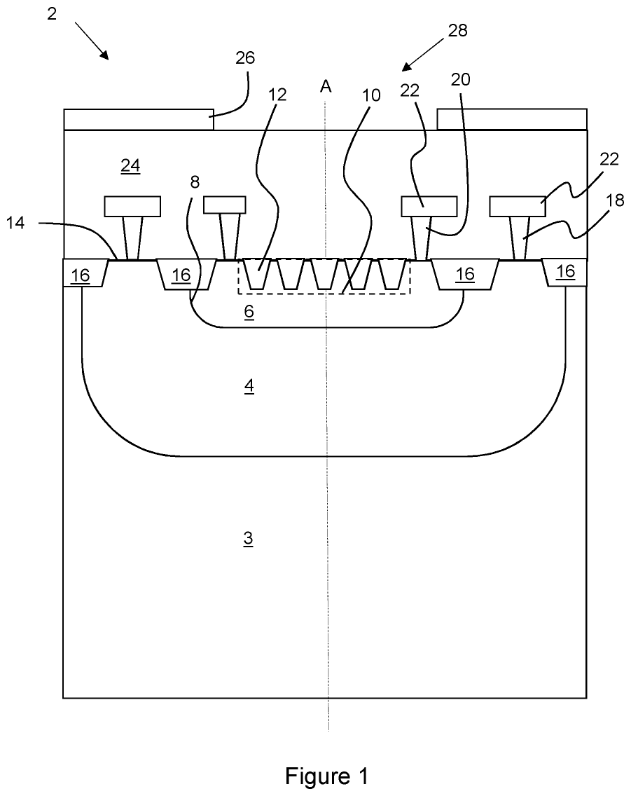

FIG. 1 shows a photodiode 2 for UV detection. The photodiode 2 comprises a silicon wafer 3 comprising a first, n-doped, well 4 connected to the cathode of the photodiode 2, and a second, p-doped, well 6 connected to the anode of the photodiode 2. A pn-junction 8 is formed between the first well 4 and the second well 6. A patterned layer 10 being an effective medium comprising trenches 12 filled with oxide is located at the surface 14 of the silicon wafer 3 in the second well 6 in order to reduce reflection losses at the interface. The trenches 12 may be round or hexagonal holes arranged in an array to cover the light sensitive area associated with the pn-junction 8. The different well regions 4 and 6 are separated along the surface 14 by STI 16. A cathode contact 18 is connected to the first well 4, and an anode contact 20 is connected to the second well 6. Both contacts 18 and 20 are connected to a first metal layer 22 of a backend stack 24 of the photodiode 2. The backend stack 24 also comprises a passivation layer 26, with a UV window 28 overlapping the light sensitive area of the photodiode. Carriers generated by light absorbed in the p-doped well 6 are pushed by the inherent electric field due to the continuously falling doping profile towards the pn-junction 8. In particular, the doping concentration in the silicon at the interface between the trenches 12 and the silicon in the second well 6 is increased and continuously decreasing away from the interface, thereby reducing the risk of charge carriers being influenced at the interface. This influence can be due to changes in the electric field. For example, if the dielectric layers on top of the silicon change their trapped charge level.

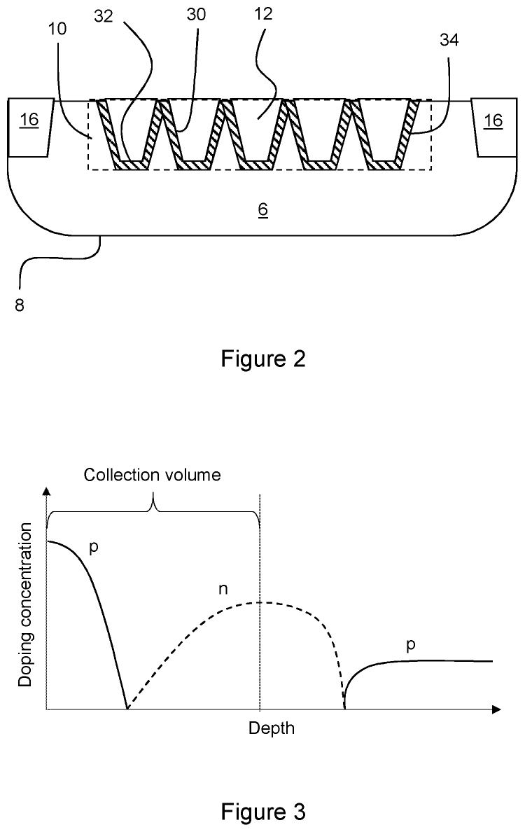

FIG. 2 shows an enlarged diagram of the second well 6 of the photodiode 2 shown in FIG. 1. The second well 6 comprises the patterned layer 10 comprising trenches 12 filled with oxide forming an effective medium with a refractive index between that of silicon and silicon oxide. Each trench 12 comprises sides 30 and a bottom 32. A layer 34 with increased doping concentration (relative to the rest of the well 6) runs along the interface (i.e. along the sides 30 and bottom 32 of the trenches 12) between the oxide in the trenches 12 and the silicon in the well 6. The layer with increased doping can reduce the risk of charge carriers generated close to the interface from becoming trapped.

FIG. 3 is schematic graph of the doping profile of the photodiode, with the doping concentration plotted against the depth along the line A shown in FIG. 1. The depth starts at the bottom of the trench 12 and runs into the epitaxial silicon of the wafer 3. The doping concertation falls continuously with depth in the p-doped well 6 towards the pn-junction 8. Charge carriers generated in this region will be pushed by the intrinsic electric field towards the pn-junction 8. The doping concentration decreases continuously from a peak concentration in the p-doped region towards the pn-junction, defining a collection volume, within which generated charge carriers are pushed to the pn-junction by the intrinsic electric field.

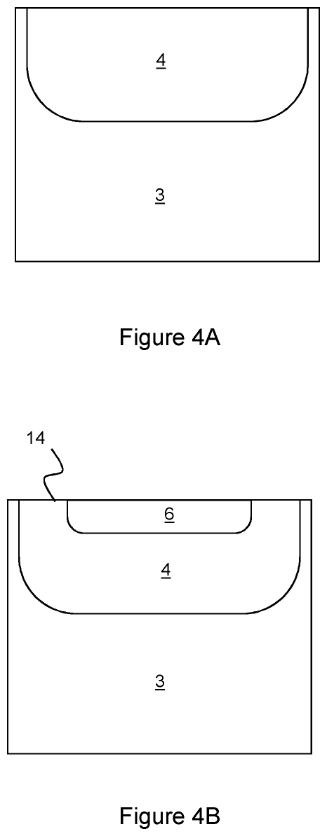

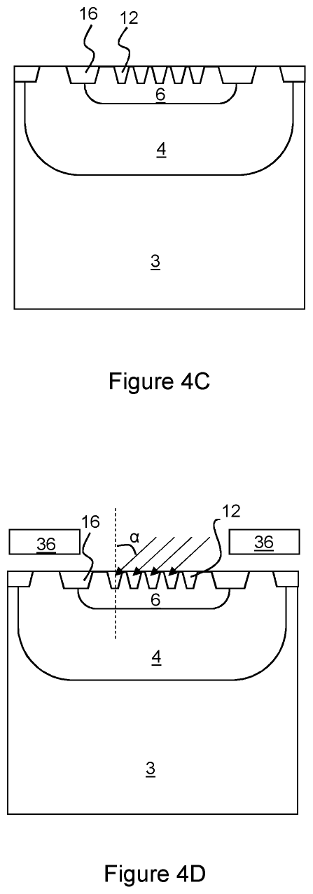

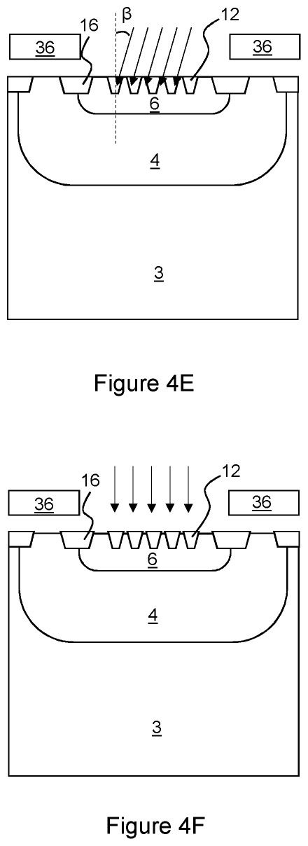

FIGS. 4A to 4F show a sequence of steps of a method of forming a photodiode.

FIG. 4A shows the wafer 3 with a first well 4 formed. The first well 4 is formed by injecting phosphorus (P) as dopant with an injection energy of 2 MeV to 3 MeV and so as to create a peak concentration in the range of 1e15 cm⁻³ to 1e19 cm⁻³.

FIG. 4B shows the wafer 3 after forming the second well 6 at the surface 14 of the wafer 3 before STI. The second well 6 is formed by injecting boron (B) with an injection energy of 10 keV to 20 keV and so as to create a peak concentration in the range of 1e14 cm⁻³ to 1e18 cm⁻³.

FIG. 4C shows the wafer 3 after forming trenches 12 and 16 in the surface 14 of the wafer 3 before filling with oxide. The trenches 16 for isolation and the (smaller) trenches 12 for forming an effective medium are formed using STI technology.

FIG. 4D shows a step of doping wherein BF2 dopants are injected at an angle α and with an injection energy of 20 keV and 30 keV using a mask 36. The doping step is performed after the STI liner oxide anneal (to form a thin layer of silicon oxide in the trenches 12), and before the STI oxide fill (deposition). The angle α of injection is in the range of 30° to 45° so as to dope the sides of the trenches 12. The wafer or injection source is rotated about a normal to the surface 14 and the injection repeated from at least four different directions, to provide uniform doping of the sides around the trenches 12. The injection angle α relative to the normal remains the same for each injection of the doping step.

FIG. 4E shows another step of doping wherein BF2 dopants are injected at another angle β, which is less than the injection angle α of the previous doping step. The doping step is performed before the STI oxide fill (deposition). The doping is performed with an injection energy in the range of 10 keV to 25 keV and is in general less than the injection energy of the previous doping step described in association with FIG. 4D above. The same mask 36 is used in this doping step, as it is the same region of the wafer 3 that is being doped. The injection angle β is in the range of 1° to 10° in order to dope the bottom of the trenches 12. The wafer 3 or injection source is rotated about a normal to the surface 14 and the injection repeated from at least four different directions, to provide uniform doping of the bottom of the trenches 12. The injection angle β relative to the normal remains the same for each injection of the doping step. In an alternative embodiment, the injection angle β is set to 0°, in which case the wafer and source do not need to be rotated to achieve uniform doping.

FIG. 4F shows a further step of doping after filling the STI trenches 12, 16. The further step of doping increases the doping concentration at the surface of the semiconductor wafer between the trenches 12.

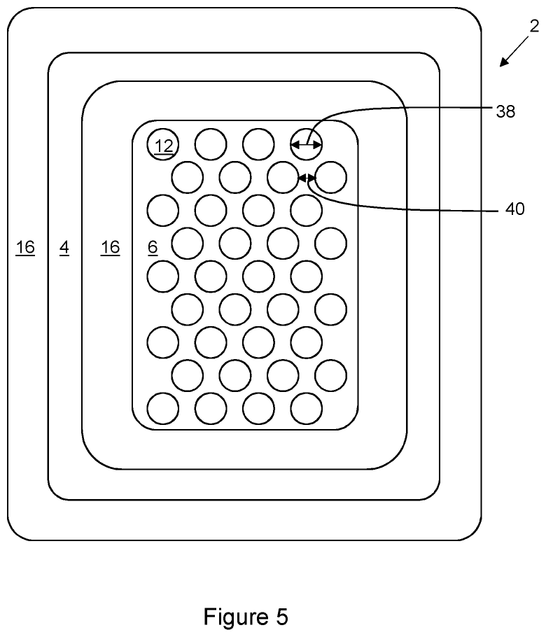

FIG. 5 shows a schematic top view of a part of a photodiode 2. The photodiode 2 comprises an array of trenches 12 being circular holes at the centre arranged to receive incident light. The holes have width 38 in the range of 220 nm to 350 nm and a spacing 40 between adjacent holes in the range of 70 nm to 210 nm. In general the spacing between the trenches 12 is smaller than the width of the trenches 12. The central (anode) area, corresponding to the underlying p-doped well 6, is surrounded by isolation 16. Outside the isolation 16 is a ring (cathode) area, corresponding to the n-doped well 4, which is in turn surrounded by outer isolation 16. The photodiode may comprise a further outer p-doped anode ring and an n-doped guard ring (not shown).

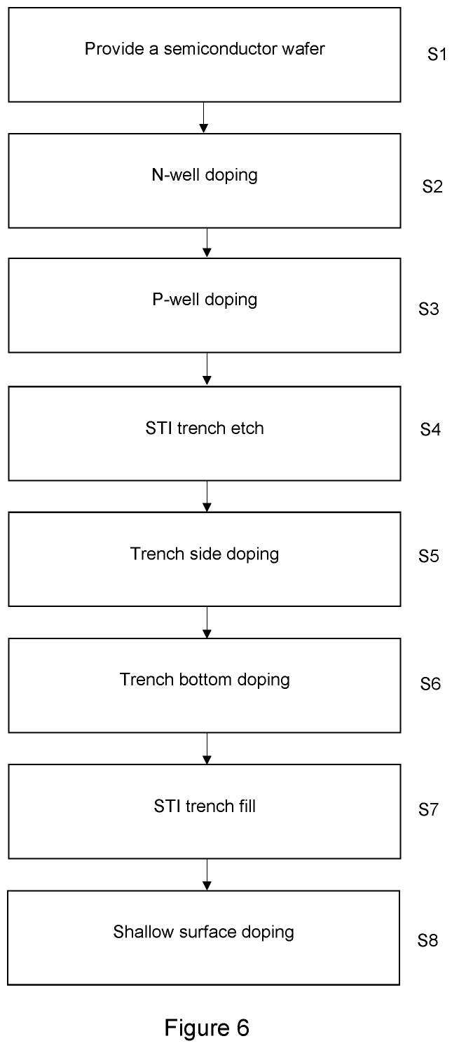

FIG. 6 shows a flow diagram of a method of forming a photodiode. The method comprises providing a semiconductor wafer (step S1). The wafer is a silicon wafer comprising a bulk silicon substrate and a doped epitaxial layer. A first doping step is performed to form an N-well in the epitaxial layer (step S2). After forming the N-well, a second step of doping is performed to form a P-well at the surface of the wafer and thereby form a pn-junction between the P-well and the N-well (step S2). After forming the pn-junction, an STI trench etch is performed to form a plurality of trenches in the P-well in the surface of the wafer (step S3). Before filling the trenches, a third doping step is performed at a relatively high angle with respect to a normal to the surface of the wafer to dope the sides of the trenches (step S4). A fourth doping step at a lesser angle is performed to dope the bottom of the trenches (step S5). After the fourth step of doping, the trenches are filled by oxide deposition (step S6). After filling the trenches, a fifth step of doping is performed to increase the doping in the p-doped well along the surface of the wafer (step S7). The method may comprise further steps as part of a backend of line (BEOL) process for forming anode and cathode contacts in order to apply a voltage across the pn-junction.

In general, the present disclosure provides a method of forming a photodiode. The method may be part of the manufacturing process of a photodetector or imaging device comprising one or more such photodiodes. The method is typically part of a complementary metal oxide semiconductor (CMOS) process, comprising a front end of line (FEOL) process for forming active semiconductor devices such as photodiodes and transistors, and a back end of line (BEOL) process for forming metal layers and contacts to the active semiconductor devices. The method comprises providing a semiconductor wafer, performing a first doping to form a first well in the wafer having a first type of doping, and performing a second doping to form a second well having a second type of doping, so as to form a pn-junction of the photodiode between the first well and the second well. The second step of doping may create a shallow p-well (or n-well) in a top layer of the wafer, which may be referred to as the active layer or diffusion layer and is typically a lightly doped epitaxial layer of silicon. The method further comprises performing a shallow trench isolation (STI) etch to form a plurality of trenches in the surface of the wafer in the second well.

High energy light (e.g. UV light) can change the charge in layers, which in turn can change the electrical field acting in the silicon. This effect causes degradation of photodiode performance from exposure to such light. The described method can provide a photodiode with a strong doping related field, which can lower or completely compensate this effect from UV exposure.

The method comprises performing a third doping by injecting dopants at a first angle relative to the surface of the wafer in order to increase a doping concentration of the second type of doping at along the sides of the trenches in the second well, and performing a fourth doping by injecting dopants at a second angle relative to the surface of the wafer in order to increase a doping concentration of the second type of doping at the bottom of the trenches in the second well. The third and fourth doping are performed after etching the trenches in the semiconductor wafer but before filling the trenches with STI material to provide a more even doping along the interface of the trenches. The method further comprises performing a fifth doping to increase a doping concentration of the second type of doping at the surface of the semiconductor wafer between the trenches in the second well, and forming a first contact for contacting the first well and forming a second contact for contacting the second well in order to apply a voltage across the pn-junction when in use. The contact formation may be part of a CMOS BEOL process further comprising forming a backend stack comprising a plurality of metal layers separated by interdielectric layers.

The first angle may be in the range of 30° to 45° with respect to a normal to the surface. This relatively high angle can allow the dopants to be efficiently injected into the sides (also referred to as sidewalls) of the trenches. The STI etch typically creates trenches (e.g. holes) having sloped sidewalls. The second angle may be in the range of 0° to 15° with respect to a normal to the surface. This relatively small angle is used to dope the substantially flat bottom of the trenches. The first, second and fifth doping may also be performed by injecting dopants having an injection angle in the range of 0° to 15° to the normal (where 0° means injection perpendicular to the surface of the semiconductor wafer). At least the third doping and in some cases all doping steps can be performed at four or more different rotation angles about a normal to the surface of the wafer. This can provide a more uniform doping in three dimensions when the injection angle is >0°. In some embodiment, six different (in one case, equidistant) rotation angles are used (e.g. at 0°, 60°, 120°, 180°, 240°, 300°).

The third doping may comprise injecting the dopants with a first injection energy, while the fourth doping comprises injecting the dopants with a second injection energy, and wherein the first injection energy is greater than the second injection energy. For example, the first injection energy may be in the range of 20 keV to 30 keV, and the second injection energy may be in the range of 10 keV to 25 keV. The dopants for the third and fourth doping may be BF2 molecules.

The first doping may comprise injecting dopants with an injection energy in the range of 2 MeV to 3 MeV. The dopants may be P atoms. The second doping may comprise injecting dopants with an injection energy in the range of 10 keV to 20 keV. The dopants may be B atoms. The fifth doping may comprise injecting dopants with an injection energy in the range of 10 keV to 20 keV. The dopants may be B atoms.

The second, third, fourth and fifth doping steps can be performed using the same mask. The second, third, fourth and fifth doping steps are performed so as to create a continuously falling doping concentration from the trenches to the pn-junction. This can reduce the risk of charge carriers getting trapped or otherwise not reaching the pn-junction for detection.

The semiconductor wafer is typically a silicon wafer comprising an epitaxial layer within which the first well and the second well are formed. In other embodiments, the wafer may be a SOI wafer comprising an epitaxial silicon layer on a buried oxide layer.

The method may further comprise forming a backend stack comprising a plurality of metal layers separated by interdielectric layers, and a nitride passivation layer, and locally removing the nitride passivation layer in a region overlapping the pn-junction (to create a so called UV window).

The trenches may comprise circular or hexagonal holes having a width in the range of 220 nm to 350 nm and a spacing from an adjacent hole in the range of 70 nm to 210 nm. In an alternative embodiment, the trenches may define raised portions (e.g. pillars or spikes) of semiconductor material left in the light sensitive region. The method may further comprise filling the trenches with silicon oxide to form a layer of an effective medium at the surface of the wafer, wherein the effective medium has a wavelength dependent refractive index n between the refractive index of silicon oxide and silicon. An optimal refractive index of the effective medium can be calculated by

$${n}_{1} = \sqrt{{n}_{0} \cdot {n}_{2}} ,$$

Wherein n0 and n2 are the refractive indices of the two materials on either side of the effective medium (in this case silicon oxide and silicon respectively). Using the second material (silicon) in forming the effective medium as described herein can be particularly advantageous for forming an effective anti-reflective coating (ARC) layer, as the refractive index of the effective medium will change substantially along with that of the second material. That is the effective medium can have similar wavelength dependence to that of the underlying material.

Also described herein is a semiconductor structure comprising a photodiode formed according to the method described above, and a sensor comprising a plurality of such photodiodes.

A particular advantage of the photodiode may be the increased sensitivity in the UVC range (about 100 nm to 280 nm wavelength) against state-of-the-art CMOS integrated devices and high performance discrete devices. Accordingly, an advantage is the ability to detect weaker signals or to save chip area as the active sensor area can be half as large for the same response and results in half capacitance. The smaller area can also provide a smaller dark current. Another advantage can be that less light is reflected and the collection volume of the device is smaller, so it is less receptive to noise and potentially faster, it may also have a higher linearity range, as the internal resistance is smaller for a similar photocurrent compared to conventional devices.

Embodiments have shown an increased reliability of the response of photodiodes against UV light stress. While most silicon based UV detectors suffer strong degradation from UV light exposure, photodiodes formed according to the described method have shown a significant decrease in such degradation. Hence, the photodiodes can perform well under UV light with little to no measurable degradation.

While specific embodiments of the invention have been described above, it will be appreciated that the invention may be practiced otherwise than as described. The descriptions above are intended to be illustrative, not limiting. It will be apparent to one skilled in the art that modifications may be made to the invention as described without departing from the scope of the claims set out below.

Each feature disclosed or illustrated in the present specification may be incorporated in the invention, whether alone or in any appropriate combination with any other feature disclosed or illustrated herein.

What is claimed is:

1. A method of forming a photodiode, the method comprising:
providing a semiconductor wafer comprising a semiconductor layer;
performing a first doping step to form a first well in the semiconductor layer having a first type of doping;
performing a second doping step to form a second well having a second type of doping, so as to form a pn-junction of the photodiode between the first well and the second well;
performing a shallow trench isolation etch to form a plurality of trenches in a surface of the semiconductor layer in the second well;
performing a third doping step by injecting dopants at a first angle relative to the surface of the wafer in order to increase a doping concentration of the second type of doping along the sides of the trenches in the second well;
performing a fourth doping step by injecting dopants at a second angle relative to the surface of the wafer in order to increase a doping concentration of the second type of doping at the bottom of the trenches in the second well;
performing a fifth doping step to increase a doping concentration of the second type of doping at the surface of the semiconductor layer between the trenches in the second well; and
forming a first contact for contacting the first well and forming a second contact for contacting the second well in order to apply a voltage across the pn-junction when in use.

2. A method of forming a photodiode, the method comprising:
providing a semiconductor wafer comprising a semiconductor layer;
performing a first doping step to form a first well in the semiconductor layer having a first type of doping;
performing a second doping step to form a second well having a second type of doping, so as to form a pn-junction of the photodiode between the first well and the second well;
performing a shallow trench isolation etch to form a plurality of raised portions of semiconductor material in a surface of the semiconductor layer in the second well;
performing a third doping step by injecting dopants at a first angle relative to the surface of the wafer in order to increase a doping concentration of the second type of doping at along the sides of the raised portions in the second well;
performing a fourth doping step by injecting dopants at a second angle relative to the surface of the wafer in order to increase a doping concentration of the second type of doping between the raised portions in the second well;
performing a fifth doping step to increase a doping concentration of the second type of doping at the surface of the semiconductor layer at a top of the raised portions in the second well; and
forming a first contact for contacting the first well and forming a second contact for contacting the second well in order to apply a voltage across the pn-junction when in use.

3. A method according to claim 1, wherein the first angle is in the range of 30° to 45° with respect to a normal to the surface.

4. A method according to claim 1, wherein the second angle is in the range of 0° to 15° with respect to a normal to the surface.

5. A method according to claim 1, wherein at least the third doping step is performed at four or more different rotation angles about a normal to the surface of the wafer.

6. A method according to claim 1, wherein the third doping step comprises injecting the dopants with a first injection energy, and wherein the fourth doping step comprises injecting the dopants with a second injection energy, wherein the first injection energy is greater than the second injection energy.

7. A method according to claim 1, wherein the second, third, fourth and fifth doping steps are performed using a same mask.

8. A method according to claim 1, wherein the second, third, fourth and fifth doping steps are performed so as to create a continuously falling doping concentration from the trenches to the pn-junction.

9. A method according to claim 1, wherein the semiconductor wafer is a silicon wafer comprising an epitaxial layer within which the first well and the second well are formed.

10. A method according to claim 1, further comprising:
forming a backend stack comprising a plurality of metal layers separated by interdielectric layers, and a nitride passivation layer; and
locally removing the nitride passivation layer in a region overlapping the pn-junction.

11. A method according to claim 1, wherein the trenches comprise circular or hexagonal holes having a width in the range of 220 nm to 350 nm and a spacing from an adjacent hole in the range of 70 nm to 210 nm.

12. A method according to claim 1, further comprising filling the trenches with silicon oxide to form a layer of an effective medium at the surface of the wafer, wherein the effective medium has a refractive index between that of silicon oxide and that of silicon.

13. A semiconductor structure comprising a photodiode formed according to the method of claim 1.

14. A sensor comprising a plurality of photodiodes formed according to the method of claim 1.
